(19) United States
(12) Patent Application Publication
(10) Pub. No.: US 2024/0145378 A1
(43) Pub. Date: May 2, 2024

(54) VIA WITH SACRIFICIAL STRESS BARRIER RING

(71) Applicant: Taiwan Semiconductor Manufacturing Company, Ltd., Hsinchu (TW)

(72) Inventors: Tzu-Ting Liu, Taoyuan (TW); Chen-Chiu Huang, Taichung (TW); Dian-Hau Chen, Taichung (TW); Hung-Chao Kao, Taipei (TW); Hsiang-Ku Shen, Hsinchu (TW); Wen-Chiung Tu, New Taipei (TW); Li Chung Yu, Kaohsiung (TW); Yu-Chung Lai, Taichung (TW)

(73) Assignee: Taiwan Semiconductor Manufacturing Company, Ltd., Hsinchu (TW)

(21) Appl. No.: 18/165,754

(22) Filed: Feb. 7, 2023

Related U.S. Application Data
(60) Provisional application No. 63/381,434, filed on Oct. 28, 2022.

(51) Int. Cl. H01L 23/522; H01L 21/768; H01L 23/528; H01L 23/58

(52) U.S. Cl. CPC H01L 23/5226; H01L 21/76816; H01L 21/76877; H01L 23/5283; H01L 23/585

(57) ABSTRACT

An interconnect structure on a semiconductor die includes: a lower conductive layer; an upper conductive layer disposed above the lower conductive layer; and a VIA disposed between the lower conductive layer and the upper conductive layer. The VIA includes: a primary interconnect structure and a sacrificial stress barrier ring disposed around the primary interconnect structure and separated a distance from the primary interconnect structure. A fabrication method for the interconnect structure includes: forming a dielectric layer over a lower conductive layer; patterning photoresist (PR) layer over the dielectric layer to define a location for a plurality of VIA trenches, wherein the patterning includes patterning the PR layer to provide a center opening for the VIA trenches that is surrounded by a ring opening for the VIA trenches, wherein the center opening and the ring opening are spaced apart.

### CROSS-REFERENCE TO RELATED APPLICATIONS

This application claims the benefit of U.S. Provisional Application No. 63/381,434, filed Oct. 28, 2022, which is incorporated herein by reference in its entirety.

### BACKGROUND

The fabrication of integrated circuits can be broadly separated into two main sections, front-end-of-the-line (FEOL) fabrication and back-end-of-the-line (BEOL) fabrication. FEOL fabrication includes the formation of devices (e.g., transistors, capacitors, resistors, etc.) within a semiconductor substrate. BEOL fabrication includes the formation of one or more metal interconnect layers comprised within one or more insulating dielectric layers disposed above the semiconductor substrate. The metal interconnect layers of the BEOL electrically connect individual devices of the FEOL to external pins of an integrated chip.

Technological advances in IC materials and design have produced generations of ICs. Each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

As feature sizes continue to decrease, fabrication processes continue to become more complex, especially with decreasing lithographic feature sizes, decreasing critical dimensions of features and decreasing pitch between features. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a is a cross-sectional view that illustrates different back-end-of-line (BEOL) interconnect layers of an example integrated circuit architecture, in accordance with some embodiments.

FIG. 2A is a diagram depicting a cross-sectional view of an example interconnect structure, in accordance with some embodiments.

FIG. 2B is a diagram depicting an example cross-section of an example configuration of an interconnect structure in a horizontal plane, in accordance with some embodiments.

FIG. 2C is a diagram depicting an example cross-section of another example configuration of an interconnect structure in a horizontal plane, in accordance with some embodiments.

FIG. 3 is a process flow chart depicting an example method for forming an interconnect structure that includes a VIA having a sacrificial stress barrier ring, in accordance with some embodiments.

FIGS. 4A-4I are diagrams depicting cross-sectional views of an example interconnect structure, which illustrate the interconnect structure at various stages of fabrication, in accordance with some embodiments.

FIGS. 5A-5E are diagrams illustrating how a sacrificial stress barrier ring can protect a primary interconnect structure in a VIA structure from negative effects of stress migration (SM), in accordance with some embodiments.

FIG. 6A is a block diagram of an example integrated circuit that includes a plurality of dies and a redistribution layer (RDL) structure for interconnecting one of the dies with another die and/or packaging pins, in accordance with some embodiments.

FIG. 6B is a diagram depicting a cross-sectional view of an example interconnect structure along a vertical plane, in accordance with some embodiments.

FIG. 6C is a diagram depicting an example cross-section of an example configuration of an interconnect structure in a horizontal plane, in accordance with some embodiments.

FIG. 6D is a diagram depicting an example cross-section of another example configuration of an interconnect structure in a horizontal plane, in accordance with some embodiments.

FIG. 7 is a process flow chart depicting an example method for forming an interconnect structure that includes a VIA having a sacrificial stress barrier ring, in accordance with some embodiments.

FIGS. 8A-8I are diagrams depicting cross-sectional views of an example interconnect structure, which illustrate the interconnect structure at various stages of fabrication, in accordance with some embodiments.

FIGS. 9A-9E are diagrams illustrating how the sacrificial stress barrier ring can protect a primary interconnect structure in a VIA structure from negative effects of SM, in accordance with some embodiments.

FIG. 10 is a diagram illustrating simulated stress gradient and hydrostatic stress characteristics for a redistribution layer (RDL) with a VIA having a sacrificial stress barrier ring, in accordance with some embodiments.

### DETAILED DESCRIPTION

The present disclosure relates generally to vertical interconnect assembly (VIA) structures used to interconnect conductors and more particularly, to VIA structures and methods of forming VIA structures with improved resistance to problems associated with stress migration (SM).

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Further, spatially relative terms, such as “beneath,” “below,” “under,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

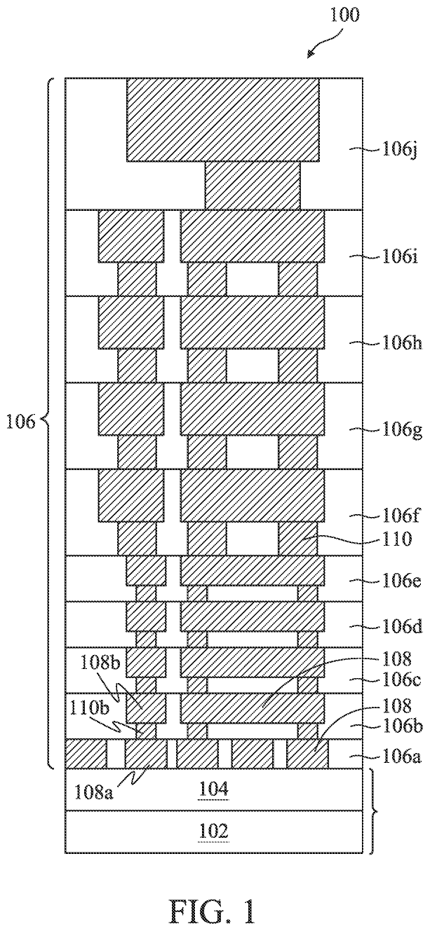

FIG. 1 is a is a cross-sectional view that illustrates different back-end-of-line (BEOL) interconnect layers 106 of an example integrated circuit architecture 100. The example integrated circuit architecture 100 includes a substrate 102, a first dielectric layer 104 over the substrate 102, and the BEOL interconnect layer 106.

The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

The substrate 102 may include various doped regions such as p-type wells or n-type wells). Doped regions may be doped with p-type dopants, such as boron or BF2, and/or n-type dopants, such as phosphorus (P) or arsenic (As). The doped regions may be formed directly on the substrate 102, in a P-well structure, in an N-well structure, or in a dual-well structure.

The substrate 102 may further include isolation features (not shown), such as shallow trench isolation (STI) features or local oxidation of silicon (LOCOS) features. Isolation features may define and isolate various device elements.

In some embodiments, the first dielectric layer 104 is an inter-layer dielectric (ILD) layer. The first dielectric layer 104 may be made of silicon oxide (SiOx), silicon nitride (SixNy) or silicon oxynitride (SiON). The example first dielectric layer 104 includes device elements (not shown) formed in the first dielectric layer 104. The device elements may include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n channel field effect transistors (PFETs/NFETs), etc.), diodes, and/or other applicable elements. Various processes are performed to form the device elements, such as deposition, etching, implantation, photolithography, annealing, and/or other applicable processes. In some embodiments, the device elements are formed in the substrate 102 in a front-end-of-line (FEOL) process.

The BEOL interconnect layer 106 may include one or more dielectric layer(s) (e.g., dielectric layers 106a, 106b, 106c, 106d, 106e, 106f, 106g, 106h, 106i, 106j) formed over the first dielectric layer 104. In some embodiments, the one or more dielectric layer(s) include an inter-layer metal (IMD) layer. The one or more dielectric layer(s) of BEOL interconnect layer 106 may be made of silicon oxide (SiOx), silicon nitride (SixNy), silicon oxynitride (SiON), dielectric material(s) with low dielectric constant (low-k), or combinations thereof.

In some embodiments, the BEOL interconnect layer 106 comprises an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the BEOL interconnect layer 106 is deposited by a chemical vapor deposition process (such as plasma enhanced chemical vapor deposition, PECVD) process or by a spin coating process.

Each dielectric layer of the BEOL interconnect layer 106 includes a number of conductive features 108. A conductive feature 108 from a lower dielectric layer can be connected to a conductive feature of a higher dielectric layer using a VIA 110 in the higher dielectric layer. For example, a conductive feature 108a of first dielectric layer 106a (lower level in this example) is connected to a conductive feature 108b of a second dielectric layer 106b (higher dielectric layer in this example) by a VIA 110b. The conductive features 108 and VIAs 110 of the BEOL interconnect layer 106 are formed from a conductive material. The conductive material may be a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy. In some embodiments, when the conductive material is made of copper (Cu) or copper based alloy, the conductive material has improved resistance values for propagating signals through the copper (Cu) interconnect at high speed.

Stress migration (SM) is a phenomenon that can occur in an integrated circuit (IC). SM can lead to voids forming within conductors that degrade the performance of an IC. For example, with SM, voids can form as result of vacancy migration and a hydrostatic stress gradient. Voids in a conductor can lead to open circuits or an increased resistance that impedes the performance of the IC.

When various materials with different thermal expansion coefficients are formed in an interconnect structure, SM can occur due to the formation of stress between different materials. Various thermal processes during BEOL processing can result in the formation of plastic deformation vacancies (e.g., small voids) in the interconnect structure. These small voids can be driven by stress migration due to the hydrostatic stress gradient to collect at high stress gradient areas in the interconnect structure to nucleate or form into a large void. Large voids can reduce or eliminate electrical contact between metal layers. Thus, SM may cause reduced electrical contact between conductive materials, which causes increased resistivity and can lead to device failure.

SM reliability issues can become more serious as geometries of semiconductor devices continue to shrink. To improve SM reliability, VIA structures disclosed herein include a primary interconnect structure and a sacrificial stress barrier ring around the primary interconnect structure. The sacrificial stress barrier ring can attract plastic deformation vacancies to prevent large voids from forming at the primary interconnect structure.

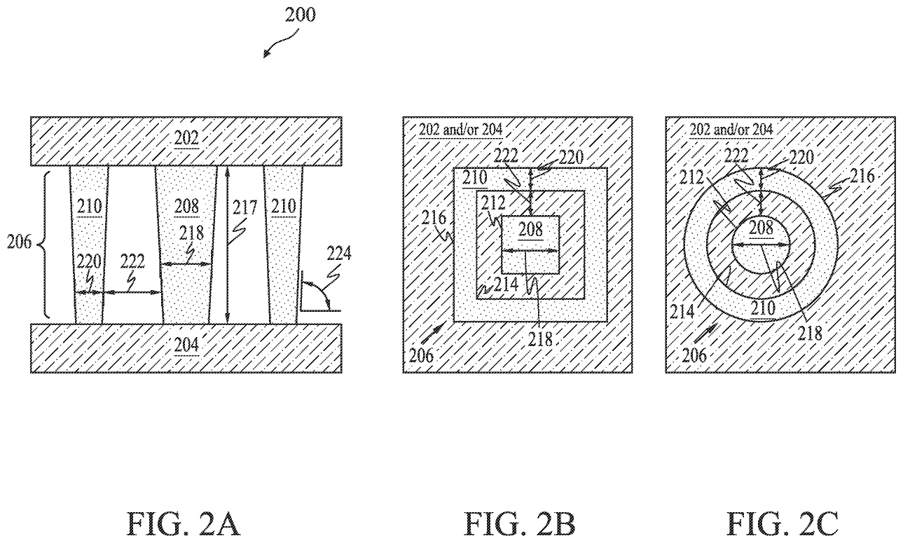

FIG. 2A depicts a cross-sectional view of an example interconnect structure 200 (such as a portion of BEOL interconnect layer 106). FIG. 2B depicts an example cross-section of an example configuration of the interconnect structure 200 in a horizontal plane. FIG. 2C depicts an example cross-section of another example configuration of the interconnect structure 200 in a horizontal plane.

The example interconnect structure 200 includes an upper conductor 202, a lower conductor 204, and a VIA 206 that interconnects the upper conductor 202 and the lower conductor 204. The upper conductor 202, lower conductor 204, and VIA 206 are formed from a conductive material that may be a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy.

The VIA 206 includes a primary interconnect structure 208 and a sacrificial stress barrier ring 210 around the primary interconnect structure 208. In various embodiments, as illustrated in the example of FIGS. 2B and 2C, a cross-section of the primary interconnect structure 208 along a horizontal plane and a cross-section of the sacrificial stress barrier ring 210 along a horizontal plane are co-centric.

As depicted in FIGS. 2B and 2C, a cross-section of the primary interconnect structure 208 along a horizontal plane and a cross-section of the sacrificial stress barrier ring 210 along a horizontal plane may take on a number of different shapes. In the example of FIG. 2B, the cross-sectional shape of both the primary interconnect structure 208 and the sacrificial stress barrier ring 210 have a square shape. In the example of FIG. 2C, the cross-sectional shape of both the primary interconnect structure 208 and the sacrificial stress barrier ring 210 have a circular shape. In other embodiments, the cross-sectional shape of the primary interconnect structure 208 may be a shape other than a square or a circle (e.g., an oval or a closed polygonal shape such as triangular, quadrilateral, pentagonal, hexagonal, heptagonal, octagonal, and others) and the cross-sectional shape of the sacrificial stress barrier ring 210 may be a shape other than a square or a circle. In some embodiments, the cross-sectional shape of the primary interconnect structure 208 may be of the same type as the cross-sectional shape of the sacrificial stress barrier ring 210. In some embodiments, the cross-sectional shape of the primary interconnect structure 208 may be of a different than the cross-sectional shape of the sacrificial stress barrier ring 210 (e.g., one could have a rectangular cross-sectional shape and the other an octagonal cross-sectional shape).

The primary interconnect structure 208 includes an outer perimeter (P_{PO}) 212 and the sacrificial stress barrier ring 210 includes both an inner perimeter (R_{IP}) 214 and an outer perimeter (R_{OP}) 216. The shape formed by the outer perimeter (P_{PO}) 212 of the primary interconnect structure 208 is spaced apart from and inside the shape formed by the inner perimeter (R_{IP}) 214 of the sacrificial stress barrier ring 210. The outer perimeter (P_{PO}) 212 of the primary interconnect structure 208 does not touch or intersect the inner perimeter (R_{IP}) 214 of the sacrificial stress barrier ring 210.

The primary interconnect structure 208 has a width (P_{W}) 218, the sacrificial stress barrier ring 210 has a width (R_{W}) 220, and the VIA 206 has a separation space (R_{S}) 222, between the primary interconnect structure 208 and the sacrificial stress barrier ring 210. The ratio of primary interconnect structure width to sacrificial stress barrier ring width to separation space can be expressed as P_{W} 218:R_{W} 220:R_{S} 222. In various embodiments, P_{W} 218:R_{W} 220:R_{S} 222=1:0.25˜1:0.25˜1.

In various embodiments, the VIA 206 has a height 217 of approximately 5 μm to approximately 6 μm, the width (R_{W}) 220 is approximately 1 μm to approximately 3 μm, and an interior angle 224 is approximately 80° to approximately 90°.

In various embodiments, a center point of a cross-sectional portion of the primary interconnect structure 208 is at the same point as a center point of a cross-sectional portion of the sacrificial stress barrier ring 210. In various embodiments, each of the primary interconnect structure 208 and the sacrificial stress barrier ring 210 comprises a diffusion barrier layer underlying a metal layer.

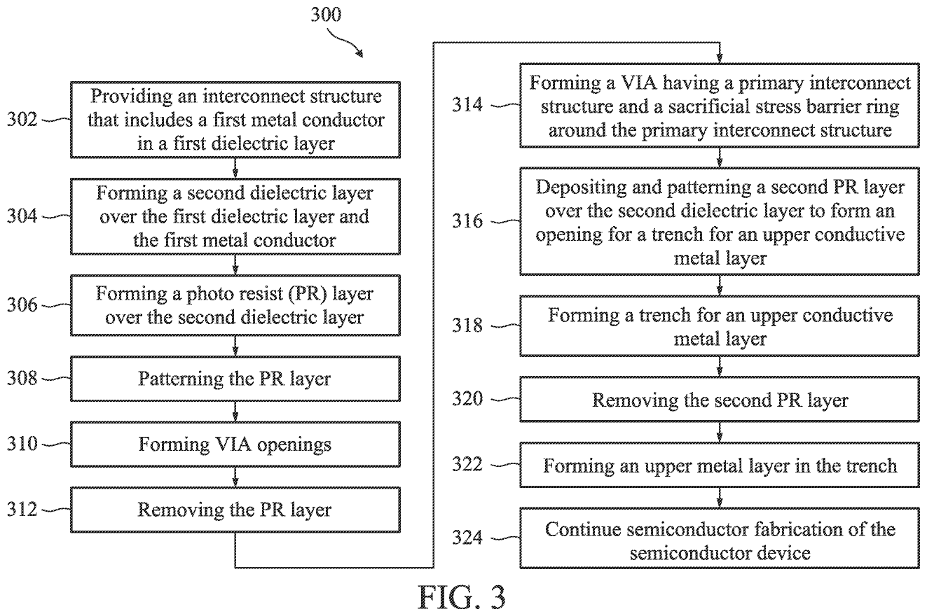

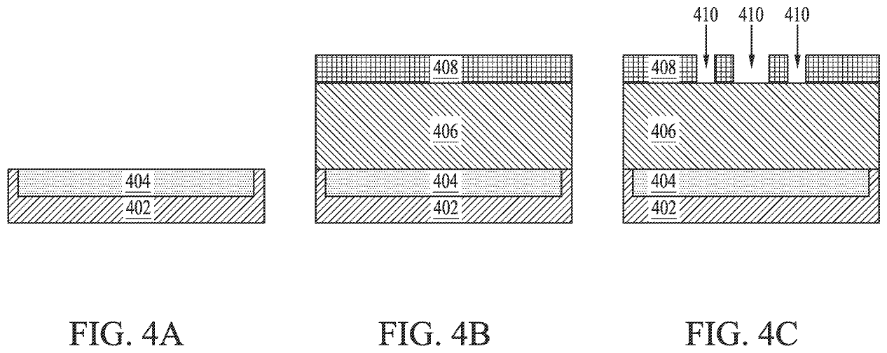

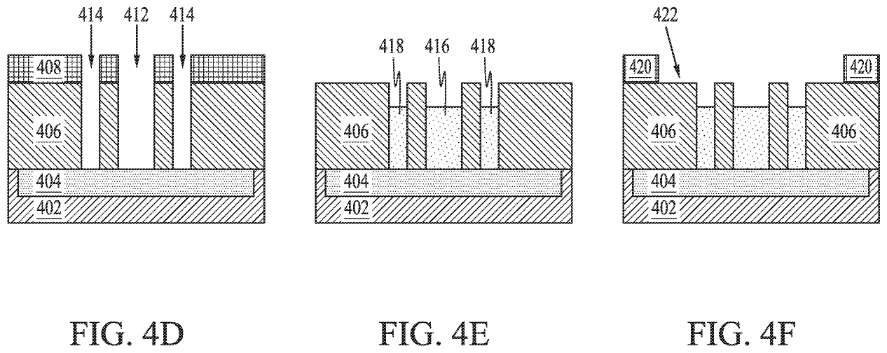

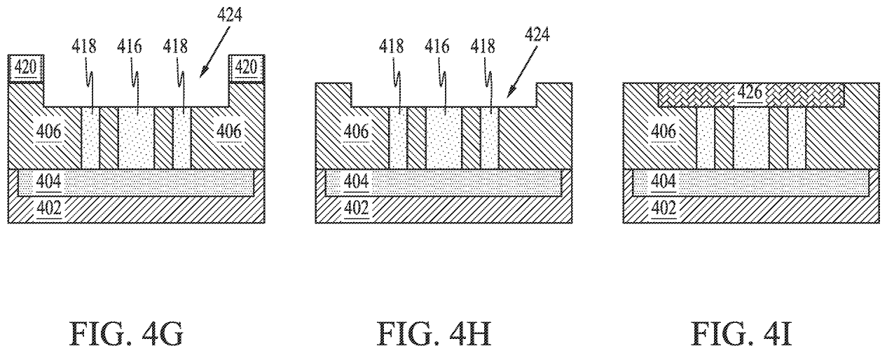

FIG. 3 is a process flow chart depicting an example method for forming an interconnect structure that includes a VIA having a sacrificial stress barrier ring. FIG. 3 is described in conjunction with FIGS. 4A-4I, which are cross-sectional views of an interconnect structure, which illustrate the interconnect structure at various stages of fabrication in accordance with some embodiments of the present disclosure of the example process 300. The process 300 is merely an example, and is not intended to limit the present disclosure beyond what is explicitly recited in the claims. Additional steps may be provided before, during, and after example process 300, and some of the steps described can be moved, replaced, or eliminated for additional embodiments of example process 300. Additional features may be added in the interconnect structure depicted in the figures and some of the features described below can be replaced, modified, or eliminated in other embodiments of the interconnect structure.

It is understood that parts of the interconnect structure may be fabricated by typical semiconductor technology process flow, and thus some processes are only briefly described herein. Moreover, it is noted that the operations of process 300, including any descriptions given with reference to the figures are merely exemplary and are not intended to be limiting beyond what is specifically recited in the claims that follow.

FIGS. 4A-4I are diagrams depicting cross-sectional views of an interconnect structure, which illustrate the interconnect structure at various stages of fabrication in accordance with some embodiments. In some figures, some reference numbers of components or features illustrated therein may be omitted to avoid obscuring other components or features; this is for ease of depicting the figures.

At block 302, the example process 300 includes providing an interconnect structure that includes a first metal conductor in a first dielectric layer. Referring to the example of FIG. 4A, in an embodiment of block 302, an interconnect structure includes a first dielectric layer 402 with a first metal conductor 404 in the dielectric layer 402.

In some embodiments, the first dielectric layer 402 is formed from silicon oxide (SiOx), silicon nitride (SixNy), silicon oxynitride (SiON), dielectric material(s) with low dielectric constant (LK), or combinations thereof. In some embodiments, the first dielectric layer 402 is formed from an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO2). In some embodiments, the first dielectric layer 402 is deposited by a chemical vapor deposition process (such as plasma enhanced chemical vapor deposition, PECVD) process or by a spin coating process. In some embodiments, the first metal conductor 404 is formed from a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy.

At block 304, the example process 300 includes forming a second dielectric layer over the first dielectric layer and the first metal conductor. In some embodiments, the second dielectric layer may include a dielectric material such as silicon oxide (SiOx), silicon nitride (SixNy), silicon oxynitride (SiON), a LK dielectric material, an ELK dielectric material, or combinations thereof. The second dielectric layer may be deposited by CVD, PECVD, spin coating and/or other suitable method.

At block 306, the example process 300 includes forming a photo resist (PR) layer over the second dielectric layer. Referring to FIG. 4B, in an embodiment of blocks 304 and 306, a second dielectric layer 406 is disposed over the first dielectric layer 402 and the first metal conductor 404. Also, a PR layer 408 is disposed over the second dielectric layer 406.

At block 308, the example process 300 includes patterning the PR layer. The PR layer is patterned to expose openings for removing a portion of the second dielectric layer to form VIA openings. In particular, the PR is patterned to provide a center opening that is surrounded by a ring opening. The patterns in the PR layer may be defined in a lithography mask, and implemented either by the transparent portions or by the opaque portions of the lithography mask. The patterns in the lithography mask may be transferred to the PR through an exposure using the lithography mask, followed by the development of the PR. Referring to the example of FIG. 4C, in an embodiment of block 308, the PR layer 408 has been patterned to expose openings 410 for removing a portion of the second dielectric layer 406 to form VIA openings.

At block 310, the example process 300 includes forming VIA openings. The VIA openings are formed by transferring the patterns in the patterned PR to the second dielectric layer 406 through an etching process to form the VIA openings. Referring to the example of FIG. 4D, in an embodiment of block 310, VIA openings comprising a first VIA trench 412 and a second VIA trench 414 are formed. The first VIA trench 412 is formed through the second dielectric layer 406 to the first metal conductor 404 and the second VIA trench 414 is also formed through the second dielectric layer 406 to the first metal conductor 404. The second VIA trench 414 is formed around the first VIA trench 412. The first VIA trench 412 and the second VIA trench 414 are formed through an etching process. The etching process may include dry etching and/or wet etching. A cross-section of the first VIA trench 412 and a cross-section of the second VIA trench 414 may take on a number of different shapes. In various embodiments, the cross-sectional shape of the first VIA trench 412 and the second VIA trench 414 may be a square, circular, oval, a closed polygonal shape, or other shape.

At block 312 the PR layer is removed and at block 314, a VIA having a primary interconnect structure and a sacrificial stress barrier ring around the primary interconnect structure is formed. Referring to the example of FIG. 4E, in an embodiment of blocks 312 and 314, a VIA having a primary interconnect structure 416 and a sacrificial stress barrier ring 418 around the primary interconnect structure 416 is formed. In various embodiments, the primary interconnect structure 416 and the sacrificial stress barrier ring 418 include a diffusion barrier layer (not shown) and conductive material. The diffusion barrier layer is used to prevent diffusion of the conductive material into the adjacent areas. The conductive material is formed from a conductive metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy. In various embodiments, the diffusion barrier layer and the conductive metal is deposited in the first VIA trench 412 and the second VIA trench 414 to form the primary interconnect structure 416 and the sacrificial stress barrier ring 418.

At block 316, a second PR layer is deposited and patterned over the second dielectric layer to form an opening for a trench for an upper conductive metal layer. Referring to the example of FIG. 4F, in an embodiment of block 316, a second PR layer 420 is deposited and patterned over the second dielectric layer 406 to form an opening 422 for a trench for an upper conductive metal layer.

At block 318, a trench for an upper conductive metal layer is formed. Referring to the example of FIG. 4G, in an embodiment of block 318, a trench 424 for an upper conductive metal layer has been formed. In an embodiment, the trench 424 has been formed through an etching process. The etching process may include dry etching and/or wet etching.

At block 320, the second PR layer is removed. The second PR layer may be removed, for example, by an ashing process. Referring to the example of FIG. 4H, in an embodiment of block 320, the second PR layer 420 has been removed from above the second dielectric layer 406.

At block 322 an upper metal layer is formed in the trench. Referring to the example of FIG. 4I, in an embodiment of block 322, an upper metal layer 426 is formed in the trench. The upper metal layer 426 includes a diffusion barrier layer (not shown) and a metal material. The diffusion barrier layer is used to prevent diffusion of the metal material into the adjacent areas. In some embodiments, the conductive material is made of metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy. In some embodiments, when the conductive material is made of copper (Cu) or copper based alloy, the conductive material has improved resistance values for propagating signals through the copper (Cu) interconnect at high speed.

At block 324 further fabrication includes continuing semiconductor fabrication of the semiconductor device. Also, additional fabrication operations not described in process 300 can occur before, between, and after the blocks 302-322 included in process 300.

A semiconductor device may undergo further processing to form various features and regions known in the art. For example, subsequent processing may form various contacts/vias/lines and multilayer interconnect features (e.g., metal layers and interlayer dielectrics) on the substrate,

Process 300 illustrates the formation of a VIA structure with a sacrificial stress barrier ring formed using a single damascene process. In other embodiments, a VIA structure with a sacrificial stress barrier ring can be formed using other processes such as a dual damascene process.

Stress migration (SM) can be caused by a residual stress that has been produced in forming multiple-layer wiring and is a factor that affects the reliability of a conductive structure. When various materials with different thermal expansion coefficients are formed in the interconnect structure, and therefore “stress migration (SM)” occurs due to the formation of stress between different materials. Voids form as a result of vacancy migration driven by the hydrostatic stress gradient. As a result, some small voids are formed in the interconnect structure. These small voids can collectively form into a large void. Large voids reduce or eliminate electrical contact between the metal layers. In another example, stress migration (SM) may be caused by thermal cycling and process variations such as improper annealing, chemical mechanical polish (“CMP”) processes, the conductive material fillings, or the like. Thus, stress migration may cause reduced electrical contact between conductive materials, which causes increased resistivity and can lead to device failure.

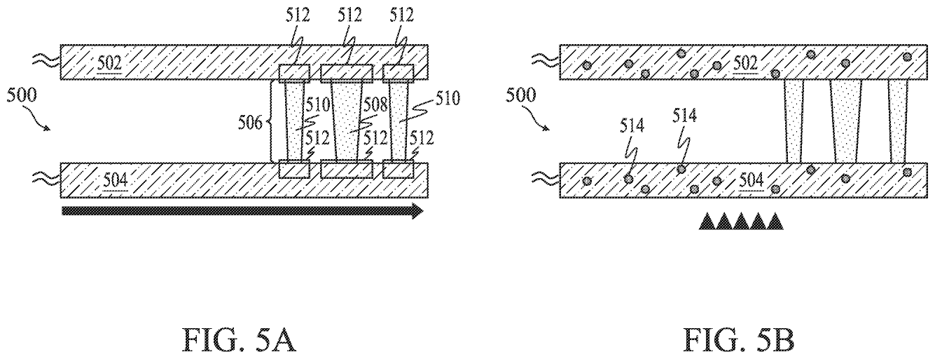

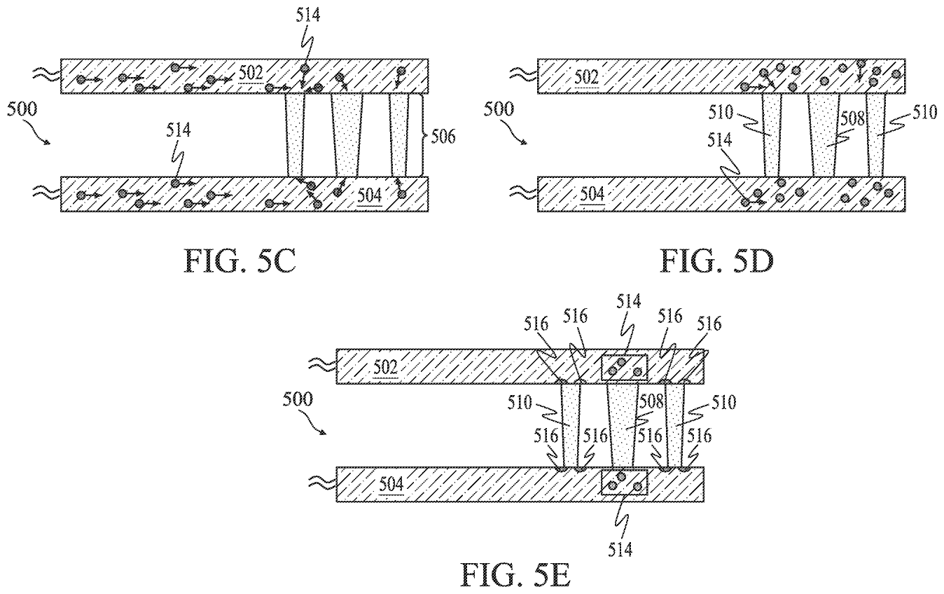

FIGS. 5A-5E are diagrams illustrating how the sacrificial stress barrier ring can protect a primary interconnect structure in a VIA structure from negative effects of SM. FIG. 5A is a diagram of an example interconnect structure 500 that includes an upper metal layer 502, a lower metal layer 504, and VIA structure 506. The VIA structure 506 includes a primary interconnect structure 508 and a sacrificial stress barrier ring 510. Also depicted are high gradient areas 512 in the interconnect structure. The high gradient areas 512 are around the intersection points of the VIA structure 506 to the upper metal layer 502 and the lower metal layer 504.

FIG. 5B is a diagram of the example interconnect structure 500 after undergoing various BEOL thermal processes. Due to BEOL thermal processes, plastic deformation vacancies 514, which are small voids, can form in the upper metal layer 502 and the lower metal layer 504.

FIG. 5C is a diagram of the example interconnect structure 500 after the effects of stress migration. Due to stress migration, the plastic deformation vacancies 514 move toward the high gradient areas around the VIA structure 506.

FIG. 5D is a diagram of the example interconnect structure 500 at a later stage after the effects of stress migration. Due to stress migration, a majority of the plastic deformation vacancies 514 begin to accumulate around the first high gradient areas they reach, which are the high gradient areas near the sacrificial stress barrier ring 510.

FIG. 5E is a diagram of the example interconnect structure at a more later stage after the effects of stress migration. Due to stress migration, a majority of the plastic deformation vacancies 514 nucleated around the first high gradient areas they reached, which are the high gradient areas near the sacrificial stress barrier ring 510, and form large voids 516 at the high gradient areas near the sacrificial stress barrier ring 510. Fewer of the plastic deformation vacancies 514 congregate near the high gradient areas around the primary interconnect structure 508. Thus, the high gradient areas around the primary interconnect structure 508 are protected from nucleation of the plastic deformation vacancies 514 and the formation of large voids.

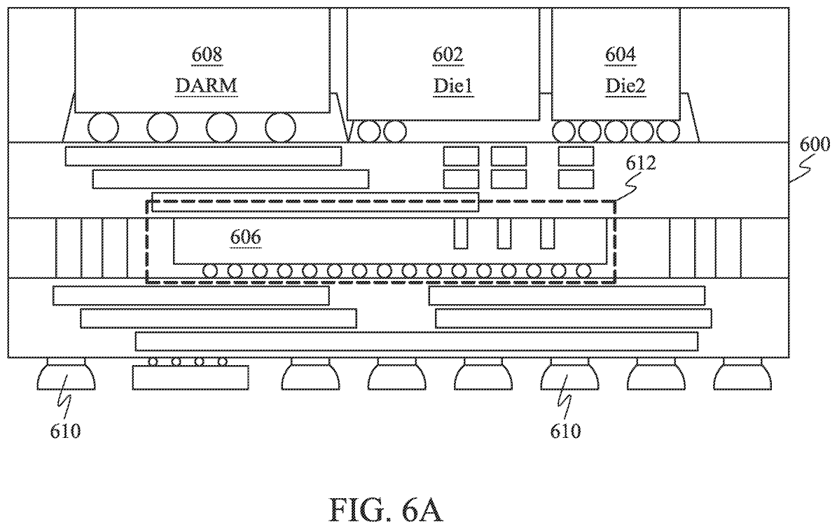

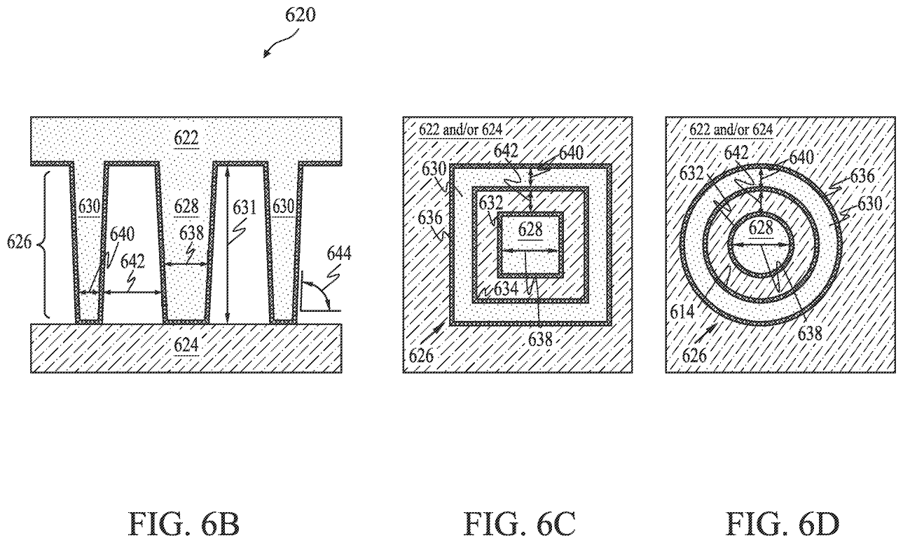

FIG. 6A is a block diagram of an example integrated circuit 600 that includes a plurality of dies and a redistribution layer (RDL) structure for interconnecting one of the dies with another die and/or packaging pins. The example integrated circuit 600 includes a first die 602, a second die 604, a third die 606, a DRAM 608, and packaging pins 610. A RDL structure 612 is included in the example integrated circuit 600 for connecting metal layers in the third die 606 with the first die 602, the second die 604, the DRAM 608, and/or packaging pins 610. The RDL structure 612 includes one or more RDL(s) that include a VIA structure having a sacrificial stress barrier ring to protect a primary interconnect structure from potential harm caused by SM.

FIGS. 6B, 6C, and 6D are diagrams illustrating example VIA structures for use with a redistribution layer (RDL). The VIA structures have a sacrificial stress barrier ring to protect a primary interconnect structure from potential harm caused by SM.

FIG. 6B depicts a cross-sectional view of an example interconnect structure 620 (such as a portion of RDL structure 612) along a vertical plane. FIG. 6C depicts an example cross-section of an example configuration of the interconnect structure 620 in a horizontal plane. FIG. 6D depicts an example cross-section of another example configuration of the interconnect structure 620 in a horizontal plane.

The example interconnect structure 620 includes an upper conductor 622, a lower conductor 624, and a VIA 626 that interconnects the upper conductor 622 and the lower conductor 624. The upper conductor 622, lower conductor 624, and VIA 626 are formed from a conductive material that may be a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy.

The VIA 626 includes a primary interconnect structure 628 and a sacrificial stress barrier ring 630 around the primary interconnect structure 628. In various embodiments, as illustrated in the example of FIGS. 6C and 6D, a cross-section of the primary interconnect structure 628 along a horizontal plane and a cross-section of the sacrificial stress barrier ring 630 along a horizontal plane are co-centric.

As depicted in FIGS. 6C and 6D, a cross-section of the primary interconnect structure 628 and a cross-section of the sacrificial stress barrier ring 630 may take on a number of different shapes. In the example of FIG. 6C, the cross-sectional shape of both the primary interconnect structure 628 and the sacrificial stress barrier ring 630 have a square shape. In the example of FIG. 6D, the cross-sectional shape of both the primary interconnect structure 628 and the sacrificial stress barrier ring 630 have a circular shape. In other embodiments, the cross-sectional shape of the primary interconnect structure 628 may be a shape other than a square or a circle (e.g., an oval or a closed polygonal shape such as triangular, quadrilateral, pentagonal, hexagonal, heptagonal, octagonal, and others) and the cross-sectional shape of the sacrificial stress barrier ring 630 may be a shape other than a square or a circle. In some embodiments, the cross-sectional shape of the primary interconnect structure 628 may be of the same type as the cross-sectional shape of the sacrificial stress barrier ring 630. In some embodiments, the cross-sectional shape of the primary interconnect structure 628 may be of a different type than the cross-sectional shape of the sacrificial stress barrier ring 630 (e.g., one could have a rectangular cross-sectional shape and the other an octagonal cross-sectional shape).

The primary interconnect structure 628 includes an outer perimeter (P_{PO}) 632 and the sacrificial stress barrier ring 630 includes both an inner perimeter (R_{IP}) 634 and an outer perimeter (R_{OP}) 636. The shape formed by the outer perimeter (P_{PO}) 632 of the primary interconnect structure 628 is spaced apart from and inside the shape formed by the inner perimeter (R_{IP}) 634 of the sacrificial stress barrier ring 630. The outer perimeter (P_{PO}) 632 of the primary interconnect structure 628 does not touch or intersect the inner perimeter (R_{IP}) 634 of the sacrificial stress barrier ring 630.

The primary interconnect structure 628 has a width (P_{W}) 638, the sacrificial stress barrier ring 630 has a width (R_{W}) 640, and the VIA 626 has a separation space (R_{S}) 642, between the primary interconnect structure 628 and the sacrificial stress barrier ring 630. The ratio of primary interconnect structure width to sacrificial stress barrier ring width to separation space can be expressed as P_{W} 638:R_{W} 640:R_{S} 642. In various embodiments, P_{W} 638:R_{W} 640:R_{S} 642=1:0.25˜1:0.25˜1.

In various embodiments, the VIA 626 has a height 631 of approximately 5 μm to approximately 6 μm, the width (R_{W}) 640 of approximately 1 μm to approximately 3 μm, and an interior angle 644 is approximately 80° to approximately 90°.

In various embodiments, a center point of a cross-sectional portion of the primary interconnect structure 628 is at the same point as a center point of a cross-sectional portion of the sacrificial stress barrier ring 630. In various embodiments, each of the primary interconnect structure 628 and the sacrificial stress barrier ring 630 comprises a diffusion barrier layer underlying a metal layer.

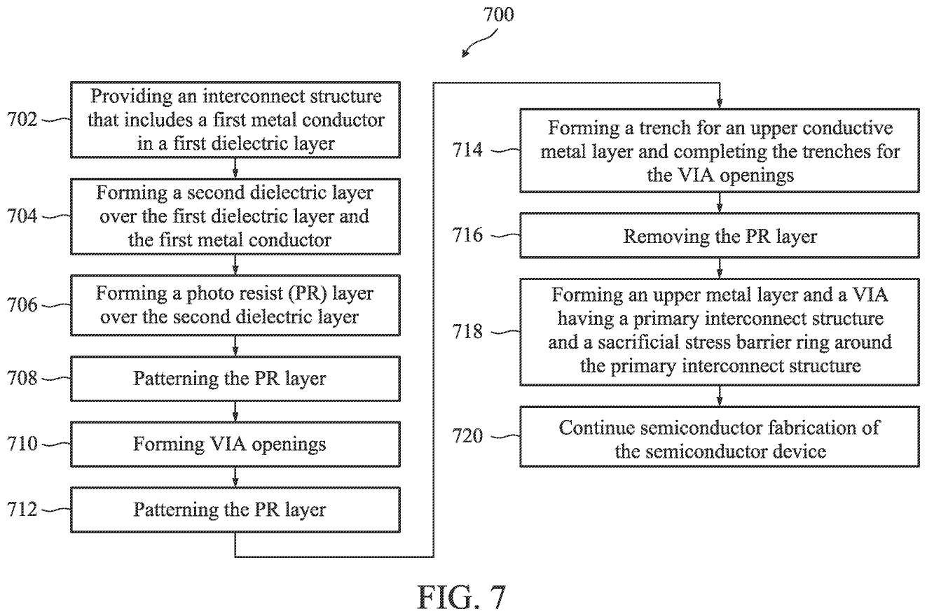

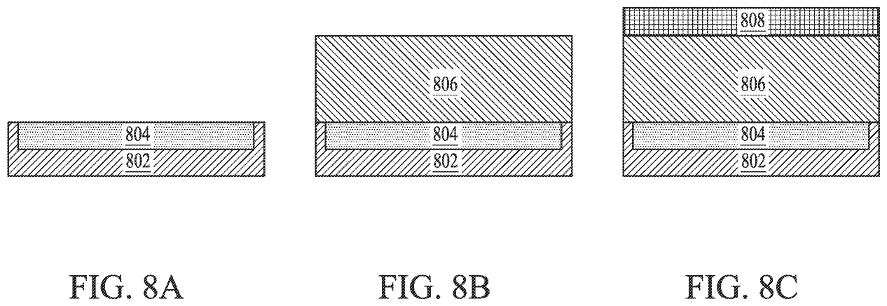

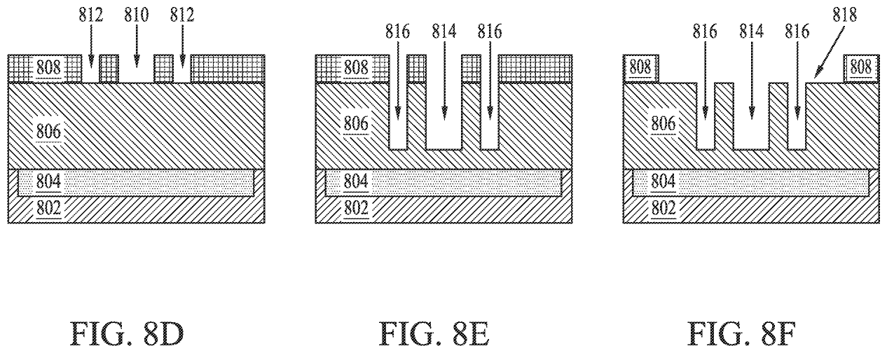

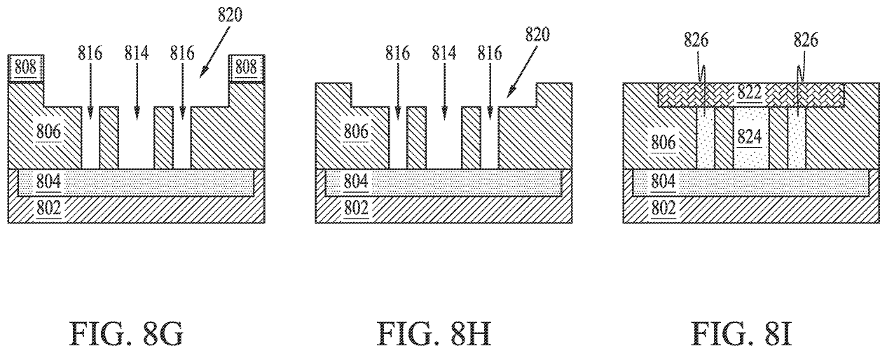

FIG. 7 is a process flow chart depicting an example method for forming an interconnect structure that includes a VIA having a sacrificial stress barrier ring. FIG. 7 is described in conjunction with FIGS. 8A-8I, which are cross-sectional views of an interconnect structure, which illustrate the interconnect structure at various stages of fabrication in accordance with some embodiments of the present disclosure of the example process 700. The process 700 is merely an example, and is not intended to limit the present disclosure beyond what is explicitly recited in the claims. Additional steps may be provided before, during, and after example process 700, and some of the steps described can be moved, replaced, or eliminated for additional embodiments of example process 700. Additional features may be added in the interconnect structure depicted in the figures and some of the features described below can be replaced, modified, or eliminated in other embodiments of the interconnect structure.

It is understood that parts of the interconnect structure may be fabricated by typical semiconductor technology process flow, and thus some processes are only briefly described herein. Moreover, it is noted that the operations of process 700, including any descriptions given with reference to the figures are merely exemplary and are not intended to be limiting beyond what is specifically recited in the claims that follow.

FIGS. 8A-8I are diagrams depicting cross-sectional views of an interconnect structure, which illustrate the interconnect structure at various stages of fabrication in accordance with some embodiments. In some figures, some reference numbers of components or features illustrated therein may be omitted to avoid obscuring other components or features; this is for ease of depicting the figures.

At block 702, the example process 700 includes providing an interconnect structure that includes a first metal conductor in a first dielectric layer. Referring to the example of FIG. 8A, in an embodiment of block 702, a first dielectric layer 802 with a first metal conductor 804 in the dielectric layer 802 of an interconnect structure is provided.

In some embodiments, the first dielectric layer 802 is formed from silicon oxide (SiOx), silicon nitride (SixNy), silicon oxynitride (SiON), dielectric material(s) with low dielectric constant (LK), or combinations thereof. In some embodiments, the first dielectric layer 802 is formed from an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the first dielectric layer 802 is deposited by a chemical vapor deposition process (such as plasma enhanced chemical vapor deposition, PECVD) process or by a spin coating process. In some embodiments, the first metal conductor 804 is formed from a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy.

At block 704, the example process 700 includes forming a second dielectric layer over the first dielectric layer and the first metal conductor. In some embodiments, the second dielectric layer may include a dielectric material such as silicon oxide (SiOx), silicon nitride (SixNy), silicon oxynitride (SiON), a LK dielectric material, an ELK dielectric material, or combinations thereof. The second dielectric layer may be deposited by CVD, PECVD, spin coating and/or other suitable method. Referring to FIG. 8B, in an embodiment of block 704, a second dielectric layer 806 is disposed over the first dielectric layer 802 and the first metal conductor 804.

At block 706, the example process 700 includes forming a photo resist (PR) layer over the second dielectric layer. Referring to FIG. 8C, in an embodiment of block 706, a PR layer 808 is disposed over the second dielectric layer 806.

At block 708, the example process 700 includes patterning the PR layer. The PR layer is patterned to expose openings for removing a portion of the second dielectric layer to form VIA openings. In particular, the PR is patterned to provide a center opening that is surrounded by a ring opening. The patterns in the PR layer may be defined in a lithography mask, and implemented either by the transparent portions or by the opaque portions of the lithography mask. The patterns in the lithography mask may be transferred to the PR through an exposure using the lithography mask, followed by the development of the PR. Referring to the example of FIG. 8D, in an embodiment of block 708, the PR layer 808 is patterned to expose a center opening 810 that is surrounded by a ring opening 812 for removing a portion of the second dielectric layer 806 to form VIA openings.

At block 710, VIA openings are formed. The VIA openings are formed by transferring the patterns in the patterned PR to the second dielectric layer 806 through an etching process to form the VIA openings. Referring to the example of FIG. 8E, in an embodiment of block 710, VIA openings comprising a first VIA trench 814 and a second VIA trench 816 are formed. The first VIA trench 814 is formed through the second dielectric layer 806 but not to the first metal conductor 804 and the second VIA trench 816 is also formed through the second dielectric layer 806 but not to the first metal conductor 804. The second VIA trench 816 is formed around the first VIA trench 814. The first VIA trench 814 and the second VIA trench 816 are formed through an etching process. The etching process may include dry etching and/or wet etching.

At block 712 the PR layer is further patterned to define an opening for a trench for an upper conductive metal layer. Referring to the example of FIG. 8F, in an embodiment of block 712, the PR layer 808 is further patterned to define an opening 818 for a trench for an upper conductive metal layer.

At block 714, a trench for an upper conductive metal layer is formed and the trenches for the VIA openings are completed. Referring to the example of FIG. 8G, in an embodiment of block 714, an upper conductive metal layer trench 820 is formed. Also, the first VIA trench 814 is completed through the second dielectric layer 806 to the first metal conductor 804 and the second VIA trench 816 is also completed through the second dielectric layer 806 to the first metal conductor 804. The upper conductive metal layer trench 820, the first VIA trench 814, and the second VIA trench 816 are formed through an etching process. The etching process may include dry etching and/or wet etching. A cross-section of the first VIA trench 814 and a cross-section of the second VIA trench 816 may take on a number of different shapes. In various embodiments, the cross-sectional shape of the first VIA trench 814 and the second VIA trench 816 may be a square, circular, oval, a closed polygonal shape, or other shape.

At block 716, the PR layer is removed. The second PR layer may be removed, for example, by an ashing process. Referring to the example of FIG. 8H, in an embodiment of block 716, the PR layer 808 has been removed from above the second dielectric layer 806.

At block 718, an upper metal layer and a VIA having a primary interconnect structure and a sacrificial stress barrier ring around the primary interconnect structure are formed. Referring to the example of FIG. 8I, in an embodiment of block 718, an upper metal layer 822 is formed in the upper conductive metal layer trench 820. Also, a VIA having a primary interconnect structure 824 and a sacrificial stress barrier ring 826 around the primary interconnect structure 824 is formed. In various embodiments, the upper metal layer 822 includes a diffusion barrier layer (not shown) and a metal material. In various embodiments, each of the upper metal layer 822, primary interconnect structure 824, sacrificial stress barrier ring 826 is formed in a conductive layer that includes a diffusion barrier layer and conductive material. The diffusion barrier layer is used to prevent diffusion of metal material into adjacent areas. In some embodiments, the conductive material is made of a metal, such as copper (Cu), copper alloy, aluminum (Al), aluminum alloy, tungsten (W), tungsten alloy, titanium (Ti), titanium alloy, tantalum (Ta) or tantalum alloy, silver (Ag) or silver alloy, gold (Au) or gold alloy. In some embodiments, when the conductive material is made of copper (Cu) or copper based alloy, the conductive material has improved resistance values for propagating signals through the copper (Cu) interconnect at high speed. In various embodiments, the diffusion barrier layer and the conductive material are deposited in the upper conductive metal layer trench 820, the first VIA trench 814, and the second VIA trench 816 to form the upper metal layer 822, the primary interconnect structure 824, and the sacrificial stress barrier ring 826.

At block 720, the example process 700 includes continuing semiconductor fabrication of the semiconductor device. Also, additional fabrication operations not described in process 700 can occur before, between, and after the blocks 702-724 included in process 700. A semiconductor device may undergo further processing to form various features and regions known in the art.

Process 700 illustrates the formation of a VIA structure with a sacrificial stress barrier ring formed using a dual damascene process. In other embodiments, a VIA structure with a sacrificial stress barrier ring can be formed using other processes such as a single damascene process.

Stress migration (SM) can be caused by a residual stress that has been produced in forming multiple-layer wiring and is a factor that affects the reliability of a conductive structure. When various materials with different thermal expansion coefficients are formed in the interconnect structure, and therefore “stress migration (SM)” occurs due to the formation of stress between different materials. Voids form as a result of vacancy migration driven by the hydrostatic stress gradient. As a result, some small voids are formed in the interconnect structure. These small voids can collectively form into a large void. Large voids reduce or eliminate electrical contact between the metal layers. In another example, stress migration (SM) may be caused by thermal cycling and process variations such as improper annealing, chemical mechanical polish (“CMP”) processes, the conductive material fillings, or the like. Thus, stress migration may cause reduced electrical contact between conductive materials, which causes increased resistivity and can lead to device failure.

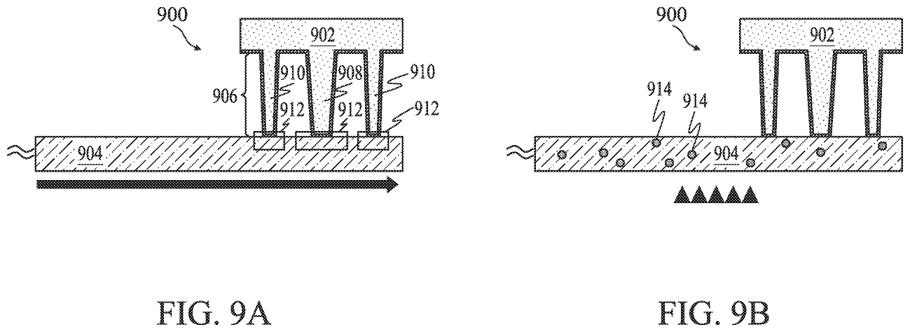

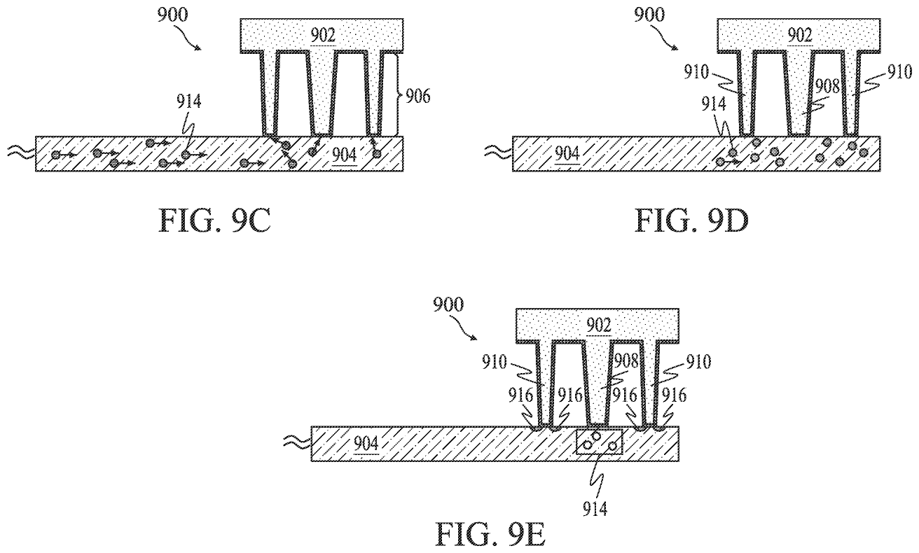

FIGS. 9A-9E are diagrams illustrating how the sacrificial stress barrier ring can protect a primary interconnect structure in a VIA structure from negative effects of SM. FIG. 9A is a diagram of an example interconnect structure 900 that includes an upper metal layer 902, a lower metal layer 904 and VIA structure 906. The VIA structure 906 includes a primary interconnect structure 908 and a sacrificial stress barrier ring 910. Also depicted are high gradient areas 912 in the interconnect structure. The high gradient areas 912 are around the intersection points of the VIA structure 906 to the lower metal layer 904.

FIG. 9B is a diagram of the example interconnect structure 900 after undergoing various BEOL thermal processes. Due to BEOL thermal processes, plastic deformation vacancies 914, which are small voids, can form in the lower metal layer 904.

FIG. 9C is a diagram of the example interconnect structure 900 after the effects of stress migration. Due to stress migration, the plastic deformation vacancies 914 move toward the high gradient areas around the VIA structure 906.

FIG. 9D is a diagram of the example interconnect structure 900 at a later stage after the effects of stress migration. Due to stress migration, a majority of the plastic deformation vacancies 914 begin to accumulate around the first high gradient areas they reach, which are the high gradient areas near the sacrificial stress barrier ring 910.

FIG. 9E is a diagram of the example interconnect structure at a more later stage after the effects of stress migration. Due to stress migration, a majority of the plastic deformation vacancies 914 nucleated around the first high gradient areas they reach, which are the high gradient areas near the sacrificial stress barrier ring 910, and form large voids 916 at the high gradient areas near the sacrificial stress barrier ring 910. Fewer of the plastic deformation vacancies 914 congregate near the high gradient areas around the primary interconnect structure 908. Thus, the high gradient areas around the primary interconnect structure 908 are protected from nucleation of the plastic deformation vacancies 914 and the formation of large voids.

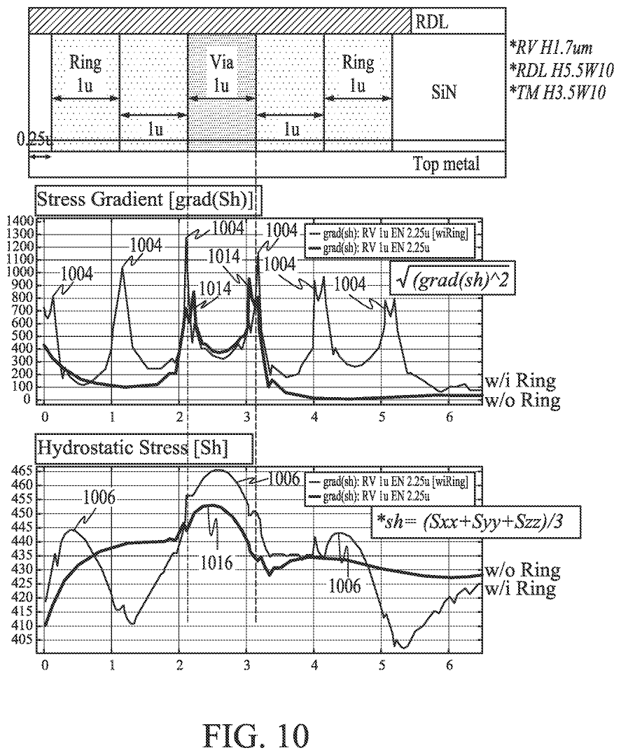

FIG. 10 is a diagram illustrating simulated stress gradient and hydrostatic stress characteristics for a RDL with a VIA having a sacrificial stress barrier ring. In this example, simulated stress gradient and hydrostatic stress characteristics around a VIA structure between an RDL layer and a top metal layer of a BEOL interconnect structure are simulated.

A plot of the simulated stress gradient illustrates that the stress gradient peaks 1004 at or near corners where the sacrificial stress barrier ring and the primary interconnect structure connect with an underlying top metal when a VIA with a ring is used. The plot of the simulated stress gradient also illustrates that the stress gradient peaks 1014 at or near corners where the VIA structure connects with an underlying top metal when a VIA without a ring is used.

A plot of the simulated hydrostatic stress illustrates that the hydrostatic stress peaks 1006 in the area where the sacrificial stress barrier ring and the primary interconnect structure connect with an underlying top metal when a VIA with a ring is used. The plot of the simulated hydrostatic stress also illustrates that the hydrostatic stress peaks 1016 in the area where the VIA structure connects with an underlying top metal when a VIA without a ring is used.

These plots illustrate that a sacrificial stress barrier ring may be helpful at attracting plastic deformation vacancies to prevent large voids from forming near the primary interconnect structure of a VIA.

Although the foregoing examples were illustrated with respect to BEOL interconnect structures and RDL structures, the foregoing apparatus, devices, and methods may also be used in connection with other semiconductor technologies that use a VIA to connect two metal layers.

In various embodiments, an interconnect structure in a semiconductor die is provided. The interconnect structure includes: a lower conductive layer; an upper conductive layer disposed above the lower conductive layer; and a vertical interconnect assembly (VIA) disposed between the lower conductive layer and the upper conductive layer. The VIA provides a conduction path between the lower conductive layer and the upper conductive layer. The VIA includes: a primary interconnect structure; and a sacrificial stress barrier ring disposed around the primary interconnect structure and separated a distance from the primary interconnect structure.

In certain embodiments of the interconnect structure, a cross-sectional portion of the primary interconnect structure along a horizontal plane has a first geometric shape, a cross-sectional portion of the sacrificial stress barrier ring along the horizontal plane has a second geometric shape, the first geometric shape has one of a square shape, a circular shape, an oval shape, or a closed polygonal shape, and the second geometric shape has a one or a square shape, a circular shape, an oval shape, or a closed polygonal shape.

In certain embodiments of the interconnect structure, a cross-sectional portion of the primary interconnect structure along a horizontal plane has a first geometric shape, a cross-sectional portion of the sacrificial stress barrier ring along the horizontal plane has a second geometric shape, and both the first geometric shape and the second geometric shape have a square shape, both have a circular shape, both have an oval shape, or both have a closed polygonal shape.

In certain embodiments of the interconnect structure, a cross-sectional portion of the primary interconnect structure along a horizontal plane has a first geometric shape, a cross-sectional portion of the sacrificial stress barrier ring along the horizontal plane has a second geometric shape, the first geometric shape has one of a square shape, a circular shape, an oval shape, or a closed polygonal shape, and the second geometric shape has a different one of the square shape, circular shape, oval shape, or closed polygonal shape.

In certain embodiments of the interconnect structure, the primary interconnect structure includes an outer perimeter (P_{PO}); the sacrificial stress barrier ring includes both an inner perimeter (R_{IP}) and an outer perimeter (R_{OP}); the outer perimeter (P_{PO}) of the primary interconnect structure does not touch or intersect the inner perimeter (R_{IP}) of the sacrificial stress barrier ring.

In certain embodiments of the interconnect structure, the primary interconnect structure has a width P_{W}; the sacrificial stress barrier ring has a width R_{W}; the VIA has a separation space R_{S} between the primary interconnect structure and the sacrificial stress barrier ring; and a ratio of P_{W}:R_{W}:R_{S}=1:0.25˜1:0.25˜1.

In certain embodiments of the interconnect structure, the VIA has an interior angle of approximately 80° to approximately 90°.

In certain embodiments of the interconnect structure, a center point of a cross-sectional portion of the primary interconnect structure is co-centric with a center point of a cross-sectional portion of the sacrificial stress barrier ring.

In certain embodiments of the interconnect structure, the lower conductive layer includes one layer of a back-end-of-line (BEOL) interconnect structure in a die; and the upper conductive layer includes a higher layer in the BEOL interconnect structure in the die.

In certain embodiments of the interconnect structure, the upper conductive layer includes a next higher layer in the BEOL interconnect structure.

In certain embodiments of the interconnect structure, the lower conductive layer includes an upper layer in a back-end-of-line (BEOL) interconnect structure in a die in an integrated circuit; and the upper conductive layer includes a redistribution layer (RDL) that connects the lower conductive layer to another die or chip packaging pins in the integrated circuit.

In certain embodiments of the interconnect structure, the lower conductive layer includes a first redistribution layer (RDL) that connects to a metal layer in a first die; and the upper conductive layer includes a second redistribution layer (RDL) that connects the lower conductive layer to another die or chip packaging pins in the integrated circuit.

In certain embodiments of the interconnect structure, each of the primary interconnect structure and the sacrificial stress barrier ring includes a diffusion barrier layer underlying a metal layer.

In various embodiments, a fabrication method is disclosed. The fabrication method includes: forming a dielectric layer over a lower conductive layer; patterning a photoresist (PR) layer over the dielectric layer to define a location for a plurality of VIA trenches and a conductive layer trench for an upper conductive layer in the dielectric layer, wherein patterning the PR layer to define a location for the plurality of VIA trenches includes patterning the PR layer to provide a center opening for the VIA trenches that is surrounded by a ring opening for the VIA trenches wherein the center opening and the ring opening are spaced apart; forming the plurality of VIA trenches and the conductive layer trench in the dielectric layer; and forming a VIA in the VIA trenches and an upper conductive layer in the conductive layer trench, wherein the VIA includes a primary interconnect structure and a sacrificial stress barrier ring disposed around the primary interconnect structure and separated a distance from the primary interconnect structure.

In certain embodiments of the method, the center opening has a first cross-sectional shape, the ring opening has a second cross-sectional shape, the first cross-sectional shape has one of a square shape, a circular shape, an oval shape, or a closed polygonal shape, and the second cross-sectional shape has one of a square shape, a circular shape, an oval shape, or a closed polygonal shape.

In certain embodiments of the method, patterning the PR layer includes patterning the PR layer to provide for the first cross-sectional shape and the second cross-sectional shape to be co-centric.

In certain embodiments of the method, forming the plurality of VIA trenches in the dielectric layer includes forming the plurality of VIA trenches in a back-end-of-line (BEOL) interconnect structure in a die.

In certain embodiments of the method, forming the plurality of VIA trenches in the dielectric layer includes forming the plurality of VIA trenches in a redistribution layer (RDL).

In certain embodiments of the method, forming the VIA in the VIA trenches and the upper conductive layer in the conductive layer trench includes forming the VIA and the upper conductive layer in a single damascene process or a dual damascene process.

In certain embodiments of the method, forming the VIA includes forming a diffusion barrier layer in the VIA trenches followed by forming a metal layer in the VIA trenches.

In various embodiments, an interconnect structure in a semiconductor die is provided. The interconnect structure includes: a lower conductive layer; an upper conductive layer disposed above the lower conductive layer; and a VIA disposed between the lower conductive layer and the upper conductive layer that provides a conduction path between the lower conductive layer and the upper conductive layer. The VIA includes: a primary interconnect structure having a first cross-sectional shape along a horizontal plane; and a sacrificial stress barrier ring that is disposed around the primary interconnect structure, co-centric with the primary interconnect structure, and has a second cross-sectional shape along the horizontal plane; wherein the first cross-sectional shape has one of a square shape, a circular shape, an oval shape, or a closed polygonal shape; wherein the second cross-sectional shape has one of a square shape, a circular shape, an oval shape, or a closed polygonal shape; and wherein the primary interconnect structure includes an outer perimeter (P_{PO}), the sacrificial stress barrier ring includes both an inner perimeter (R_{IP}) and an outer perimeter (R_{OP}), and the outer perimeter (P_{PO}) of the primary interconnect structure does not touch or intersect the inner perimeter (R_{IP}) of the sacrificial stress barrier ring.

In certain embodiments of the interconnect structure, both the first cross-sectional shape and the second cross-sectional shape have a square shape, both have a circular shape, both have an oval shape, or both have a closed polygonal shape.

In certain embodiments of the interconnect structure, the lower conductive layer includes one layer of a back-end-of-line (BEOL) interconnect structure in a die; and the upper conductive layer includes a higher layer in the BEOL interconnect structure in the die.

In certain embodiments of the interconnect structure, the lower conductive layer includes an upper layer in a back-end-of-line (BEOL) interconnect structure in a die in an integrated circuit; and the upper conductive layer includes a redistribution layer (RDL) that connects the lower conductive layer to another die or chip packaging pins in the integrated circuit.

In certain embodiments of the interconnect structure, the lower conductive layer includes a first redistribution layer (RDL) that connects to a metal layer in a first die; and the upper conductive layer includes a second redistribution layer (RDL) that connects the lower conductive layer to another die or chip packaging pins in the integrated circuit.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. An interconnect structure on a semiconductor die, comprising:
a lower conductive layer;
an upper conductive layer disposed above the lower conductive layer; and
a vertical interconnect assembly (VIA) disposed between the lower conductive layer and the upper conductive layer that provides a conduction path between the lower conductive layer and the upper conductive layer, the VIA comprising:
a primary interconnect structure; and
a sacrificial stress barrier ring disposed around the primary interconnect structure and separated a distance from the primary interconnect structure.

2. The interconnect structure of claim 1, wherein a cross-sectional portion of the primary interconnect structure along a horizontal plane has a first geometric shape, a cross-sectional portion of the sacrificial stress barrier ring along the horizontal plane has a second geometric shape, the first geometric shape has one of a square shape, a circular shape, an oval shape, or a closed polygonal shape, and the second geometric shape has a one or a square shape, a circular shape, an oval shape, or a closed polygonal shape.

3. The interconnect structure of claim 1, wherein a cross-sectional portion of the primary interconnect structure along a horizontal plane has a first geometric shape, a cross-sectional portion of the sacrificial stress barrier ring along the horizontal plane has a second geometric shape, and both the first geometric shape and the second geometric shape have a square shape, both have a circular shape, both have an oval shape, or both have a closed polygonal shape.

4. The interconnect structure of claim 1, wherein:
the primary interconnect structure includes an outer perimeter (P_{PO});
the sacrificial stress barrier ring includes both an inner perimeter (R_{IP}) and an outer perimeter (R_{OP}); and
the outer perimeter (P_{PO}) of the primary interconnect structure does not touch or intersect the inner perimeter (R_{IP}) of the sacrificial stress barrier ring.

5. The interconnect structure of claim 1, wherein:
the primary interconnect structure has a width P_{W};
the sacrificial stress barrier ring has a width R_{W};
the VIA has a separation space R_{S} between the primary interconnect structure and the sacrificial stress barrier ring; and
a ratio of P_{W}:R_{W}:R_{S}=1:0.25˜1:0.25˜1.

6. The interconnect structure of claim 1, wherein:
the lower conductive layer comprises one layer of a back-end-of-line (BEOL) interconnect structure in a die; and
the upper conductive layer comprises a higher layer in the BEOL interconnect structure in the die.

7. The interconnect structure of claim 1, wherein:
the lower conductive layer comprises an upper layer in a back-end-of-line (BEOL) interconnect structure in a die in an integrated circuit; and
the upper conductive layer comprises a redistribution layer (RDL) that connects the lower conductive layer to another die or chip packaging pins in the integrated circuit.

8. The interconnect structure of claim 1, wherein:
the lower conductive layer comprises a first redistribution layer (RDL) that connects to a metal layer in a first die in an integrated circuit; and
the upper conductive layer comprises a second redistribution layer (RDL) that connects the lower conductive layer to another die or chip packaging pins in the integrated circuit.

9. A fabrication method, comprising:
forming a dielectric layer over a lower conductive layer;
patterning a photoresist (PR) layer over the dielectric layer to define a location for a plurality of vertical interconnect assembly (VIA) trenches and a conductive layer trench for an upper conductive layer in the dielectric layer, wherein patterning the PR layer to define a location for the plurality of VIA trenches comprises patterning the PR layer to provide a center opening for the VIA trenches that is surrounded by a ring opening for the VIA trenches wherein the center opening and the ring opening are spaced apart;
forming the plurality of VIA trenches and the conductive layer trench in the dielectric layer; and
forming a VIA in the VIA trenches and an upper conductive layer in the conductive layer trench, wherein the VIA comprises a primary interconnect structure and a sacrificial stress barrier ring disposed around the primary interconnect structure and separated a distance from the primary interconnect structure.

10. The fabrication method of claim 9, wherein the center opening has a first cross-sectional shape, the ring opening has a second cross-sectional shape, the first cross-sectional shape has one of a square shape, a circular shape, an oval shape, or a closed polygonal shape, and the second cross-sectional shape has one of a square shape, a circular shape, an oval shape, or a closed polygonal shape.

11. The fabrication method of claim 10 wherein patterning the PR layer comprises patterning the PR layer to provide for the first cross-sectional shape and the second cross-sectional shape to be co-centric.

12. The fabrication method of claim 9, wherein forming the plurality of VIA trenches in the dielectric layer comprises forming the plurality of VIA trenches in a back-end-of-line (BEOL) interconnect structure in a die.

13. The fabrication method of claim 9, wherein forming the plurality of VIA trenches in the dielectric layer comprises forming the plurality of VIA trenches in a redistribution layer (RDL).

14. The fabrication method of claim 9, wherein forming the VIA in the VIA trenches and the upper conductive layer in the conductive layer trench comprises forming the VIA and the upper conductive layer in a single damascene process or a dual damascene process.

15. The fabrication method of claim 9, wherein forming the VIA comprises forming a diffusion barrier layer in the VIA trenches followed by forming a metal layer in the VIA trenches.

16. An interconnect structure on a semiconductor die, comprising:
a lower conductive layer;
an upper conductive layer disposed above the lower conductive layer; and
a vertical interconnect assembly (VIA) disposed between the lower conductive layer and the upper conductive layer that provides a conduction path between the lower conductive layer and the upper conductive layer, the VIA comprising:
a primary interconnect structure having a first cross-sectional shape along a horizontal plane; and
a sacrificial stress barrier ring that is disposed around the primary interconnect structure, co-centric with the primary interconnect structure, and has a second cross-sectional shape along the horizontal plane;
wherein the first cross-sectional shape has one of a square shape, a circular shape, an oval shape, or a closed polygonal shape;
wherein the second cross-sectional shape has one of a square shape, a circular shape, an oval shape, or a closed polygonal shape; and
wherein the primary interconnect structure includes an outer perimeter (P_{PO}), the sacrificial stress barrier ring includes both an inner perimeter (R_{IP}) and an outer perimeter (R_{OP}), and the outer perimeter (P_{PO}) of the primary interconnect structure does not touch or intersect the inner perimeter (R_{IP}) of the sacrificial stress barrier ring.

17. The interconnect structure of claim 16, wherein both the first cross-sectional shape and the second cross-sectional shape have a square shape, both have a circular shape, both have an oval shape, or both have a closed polygonal shape.

18. The interconnect structure of claim 16, wherein:
the lower conductive layer comprises one layer of a back-end-of-line (BEOL) interconnect structure in a die; and
the upper conductive layer comprises a higher layer in the BEOL interconnect structure in the die.

19. The interconnect structure of claim 16, wherein:
the lower conductive layer comprises an upper layer in a back-end-of-line (BEOL) interconnect structure in a die in an integrated circuit; and
the upper conductive layer comprises a redistribution layer (RDL) that connects the lower conductive layer to another die or chip packaging pins in the integrated circuit.

20. The interconnect structure of claim 16, wherein:
the lower conductive layer comprises a first redistribution layer (RDL) that connects to a metal layer in a first die in an integrated circuit; and
the upper conductive layer comprises a second redistribution layer (RDL) that connects the lower conductive layer to another die or chip packaging pins in the integrated circuit.
